(19) United States
(12) Patent Application Publication
(10) Pub. No.: US 2026/0256015 A1
(43) Pub. Date: Aug. 27, 2026

(54) DISPLAY DEVICE, ELECTRONIC DEVICE INCLUDING THE SAME, AND METHOD OF MANUFACTURING DISPLAY DEVICE

(71) Applicant: Samsung Display Co., Ltd., Yongin-Si (KR)

(72) Inventors: SANGHYO PARK, Yongin-si (KR); JIEUN NAM, Yongin-si (KR); YUNYOUNG LEE, Yongin-si (KR); IN SOO PARK, Yongin-si (KR)

(21) Appl. No.: 19/362,198

(22) Filed: Oct. 17, 2025

(30) Foreign Application Priority Data
Feb. 24, 2025 (KR) 10-2025-0023308

(51) Int. Cl. H01L 23/31; H10H 29/01; H10H 29/852; H10K 59/12; H10K 59/80; H10K 102/00

(52) U.S. Cl. CPC H10W 74/114; H10H 29/0362; H10H 29/852; H10K 59/1201; H10K 59/873; H10K 2102/311

(57) ABSTRACT

The display device includes a display module, a first adhesive layer, a first protection member, a second adhesive layer, and a support plate. The first adhesive layer is disposed on the display module and includes a first initiator and a second initiator that is different from the first initiator. The first protection member is disposed on the first adhesive layer. The second adhesive layer is disposed below the display module and includes a third initiator that is different from the first initiator and the second initiator. The support plate is disposed below the second adhesive layer.

### CROSS-REFERENCE TO RELATED APPLICATION(S)

This U.S. non-provisional patent application claims priority, under 35 U.S.C. § 119, of Korean Patent Application No. 10-2025-0023308 filed on Feb. 24, 2025, the entire contents of which are hereby incorporated by reference.

### BACKGROUND

The present disclosure relates to a display device, an electronic device including the same, and a method for manufacturing the display device, and more particularly, to a foldable display device having improved display quality and an electronic device including the same.

A display device presents various images on a display area to provide information to a user. In general, the display device presents information within an allocated screen.

In recent years, a flexible display device including a bendable flexible display panel has been developed. Unlike a traditional flat display device, the flexible display device may be folded, rolled, or bent like paper. The flexible display device, which is variously changeable in shape, may be carried regardless of a typical screen size, and thus user convenience may be improved.

However, since a thin material is used to realize the above-described flexible features, bending or curvature may occur in the display area where image is displayed.

### SUMMARY

The present disclosure provides a display device having a display area with a low surface roughness, thereby improving display quality and an electronic device including the same.

The present disclosure also provides a method for manufacturing a display device having a display area with a low surface roughness.

An embodiment of the inventive concept provides a display device including a display module, a first adhesive layer, a first protection member, a second adhesive layer, and a support plate. The first adhesive layer is disposed on the display module and includes a first initiator and a second initiator that is different from the first initiator. The first protection member is disposed on the first adhesive layer. The second adhesive layer is disposed below the display module and includes a third initiator that is different from the first initiator and the second initiator. The support plate is disposed below the second adhesive layer.

In an embodiment, the first initiator may be a material that initiates a polymerization reaction in response to a first predetermined temperature, and the second initiator may be a material that initiates a polymerization reaction in response to light having a predetermined wavelength.

In an embodiment, the third initiator may be a material that initiates a polymerization reaction in response to a second predetermined temperature different from the first predetermined temperature.

In an embodiment, the first initiator may include azobisisobutyronitrile, and the second initiator may include at least one of a ketone-based material and a benzil ketone-based material.

In an embodiment, a bottom surface of the first adhesive layer may have a surface roughness greater than that of a top surface of the first adhesive layer.

In an embodiment, a top surface of the second adhesive layer may have a surface roughness greater than that of the top surface of the first adhesive layer.

In an embodiment, the display device may further include: a third adhesive layer disposed on the first protection member; and a second protection member disposed on the third adhesive layer.

In an embodiment, each of the display module, the first adhesive layer, the first protection member, the second adhesive layer, the support plate, the third adhesive layer, and the second protection member may be foldable.

In an embodiment, a plurality of folding openings may be defined in the support plate, and an adhesive opening that overlaps the plurality of folding openings may be defined in the second adhesive layer.

In an embodiment, at least one of the second protection member, the third adhesive layer, the first protection member, and the first adhesive layer may have a Kc value greater than or equal to 0.1 and less than or equal to 0.2, and the Kc value may be a value measured by phase measuring deflectometry (PMD), which is a curvature value obtained by measuring a waviness having a wavelength that is greater than or equal to 1.0 mm and less than or equal to 3.0 mm.

In an embodiment of the inventive concept, an electronic device includes: a display module; a first adhesive layer, a first protection member, a second adhesive layer, and a support plate. The first adhesive layer is disposed on the display module and has a bottom surface having a surface roughness greater than that of a top surface that is opposite to the bottom surface. The first protection member is disposed on the first adhesive layer. The second adhesive layer is disposed below the display module. The support plate is disposed below the second adhesive layer.

In an embodiment, the first adhesive layer may include a first initiator and a second initiator that is different from the first initiator.

In an embodiment, the first initiator may be a material that initiates a polymerization reaction in response to a predetermined temperature, and the second initiator may be a material that initiates a polymerization reaction in response to light having a predetermined wavelength.

In an embodiment, the first initiator may include azobisisobutyronitrile, and the second initiator may include at least one of a ketone-based material and a benzil ketone-based material.

In an embodiment, the electronic device may further include: a third adhesive layer disposed on the first protection member; and a second protection member disposed on the third adhesive layer. Each of the display module, the first adhesive layer, the first protection member, the second adhesive layer, the support plate, the third adhesive layer, and the second protection member may be foldable.

In an embodiment, at least one of the second protection member, the third adhesive layer, the first protection member, and the first adhesive layer may have a Kc value greater than or equal to 0.1 and less than or equal to 0.2, and the Kc value may be a value measured by phase measuring deflectometry (PMD), which is a curvature value obtained by measuring a waviness having a wavelength that is grater than or equal to 1.0 mm and less than or equal to 3.0 mm.

In an embodiment of the inventive concept, a method for manufacturing a display device includes a preparing process, an adhesive layer arranging process, a protection member arranging process, and a flattening process. In the preparing process, a display module is prepared. In the adhesive layer arranging process, an adhesive layer is arranged on the display module, and a creep value of the adhesive layer is greater than or equal to 150% and less than or equal to 300% when a stress of 2000 Pa is applied for 10 minutes at a temperature of 25° C. In the protection member arranging process, a protection member containing a transparent material is arranged on the adhesive layer. In the flattening process, a predetermined time is waited after the protection member arranging process for the adhesive layer to flatten (decrease in roughness).

In an embodiment, the method may further include a photocuring process. In the photocuring process, the protection member may be irradiated with light having a predetermined wavelength, curing the adhesive layer.

In an embodiment, a creep value of the adhesive layer after the photocuring process may be greater than or equal to 80% and less than or equal to 130% when a stress of 2000 Pa is applied for 10 minutes at a temperature of 25° C.

In an embodiment, a bottom surface of the adhesive layer may have a surface roughness greater than that of a top surface of the adhesive layer.

In an embodiment, the predetermined time may be greater than or equal to 50 minutes and less than or equal to 24 hours.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1A is a view illustrating, as an example, an unfolded state of an electronic device according to an embodiment of the inventive concept;

FIG. 1B is a view illustrating, as an example, a folded state of the electronic device according to an embodiment of the inventive concept;

FIG. 2 is an exploded perspective view illustrating, as an example, an electronic device according to an embodiment of the inventive concept;

FIG. 3 is a view illustrating, as an example, a portion of a cross-section taken along line I-I′ of FIG. 1A;

FIG. 4 is a view illustrating, as an example, a portion of a cross-section of a display module according to an embodiment of the inventive concept;

FIG. 5 is a view illustrating, as an example, a cross-section of a display panel DP according to an embodiment of the inventive concept;

FIG. 6 is an enlarged view illustrating a portion AA of FIG. 3;

FIG. 7 is a flowchart representing a method for manufacturing a display device according to an embodiment of the inventive concept;

FIGS. 8A to 8E are views corresponding to respective processes of the method for manufacturing the display device;

FIG. 9 is a graph representing a change in roughness of a display area of the electronic device in accordance with a waiting time in a flattening process;

FIG. 10 is a view illustrating the display area of the electronic device according to an embodiment of the inventive concept and a display area of a comparative example;

FIG. 11 is a block diagram illustrating, as an example, the electronic device according to an embodiment of the inventive concept; and

FIG. 12 is a schematic view illustrating, as an example, electronic devices according to various embodiments.

### DETAILED DESCRIPTION

Hereinafter, embodiments of the inventive concept will be described with reference to the accompanying drawings.

Also, in the figures, the thickness, ratio, and dimensions of components are exaggerated for clarity of illustration. The term “and/or” includes any and all combinations of one or more of the associated listed items.

The words “include” and “comprise” are intended to specify a property, a fixed number, a step, an operation, an element, a component or a combination thereof without excluding other properties, fixed numbers, steps, operations, elements, components or combinations thereof.

A display device according to an embodiment of the inventive concept may be applied to various electronic devices. An electronic device according to an embodiment of the inventive concept may include the above-described display device and further include a module or device having an additional function in addition to the display device.

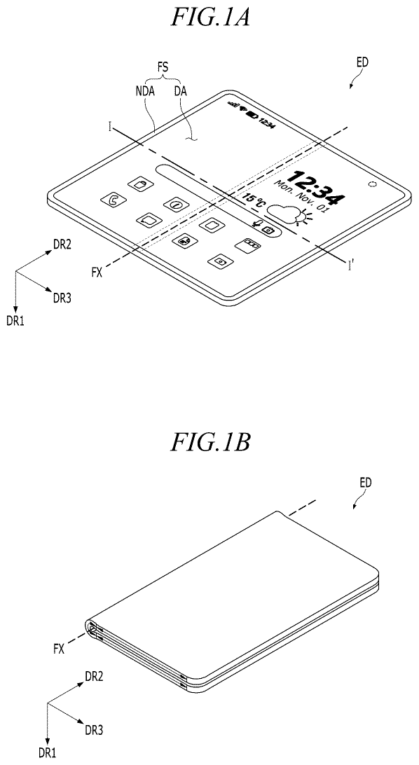

FIG. 1A is a view illustrating, as an example, an unfolded state of an electronic device ED according to an embodiment of the inventive concept. FIG. 1B is a view illustrating, as an example, a folded state of the electronic device ED according to an embodiment of the inventive concept.

A first direction DR1 may correspond to a direction of a thickness of the electronic device ED. A second direction DR2 may be perpendicular to the first direction DR1. A third direction DR3 may be perpendicular to each of the first direction DR1 and the second direction DR2.

Referring to FIG. 1A, the electronic device ED may be activated by an electrical signal. For example, the electronic device ED may display an image through a display surface FS that is parallel to each of the second direction DR2 and the third direction DR3. The display surface FS of the electronic device ED may include a display area DA and a non-display area NDA. The non-display area NDA may surround the display area DA.

Referring to FIGS. 1A and 1B, the electronic device ED may be folded about a folding axis FX extending in a direction parallel to the second direction DR2.

In this specification, in-folding refers to a state in which the electronic device ED is folded so that the display surface FS is not exposed to the outside, and out-folding refers to a state in which the electronic device ED is folded so that the display surface FS is exposed to the outside. Although in-folding of the electronic device ED is illustrated in FIG. 1B, the embodiment of the inventive concept is not limited thereto. In an embodiment of the inventive concept, the electronic device ED may be in-folded or out-folded. In another embodiment of the inventive concept, the electronic device ED may be both in-folded and out-folded.

Although the electronic device ED is illustrated as a smartphone in FIGS. 1A and 1B, the embodiment of the inventive concept is not limited thereto. In another embodiment of the inventive concept, the electronic device ED may include at least one of a large flexible display or a medium to small flexible display. For example, a large flexible display may include a television, a monitor, or an electronic billboard. A medium to small flexible display may include a tablet, a display built in home appliances, a smartwatch, or a smartphone.

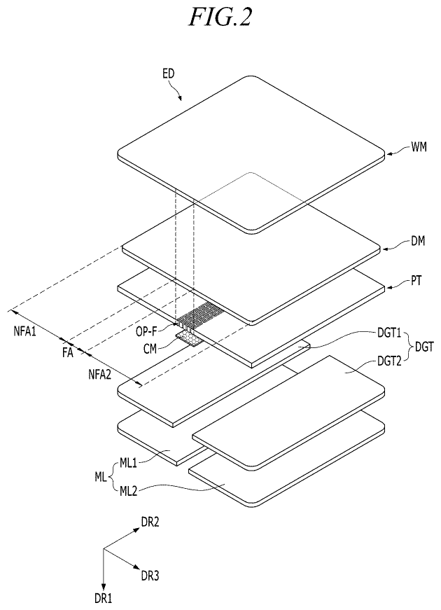

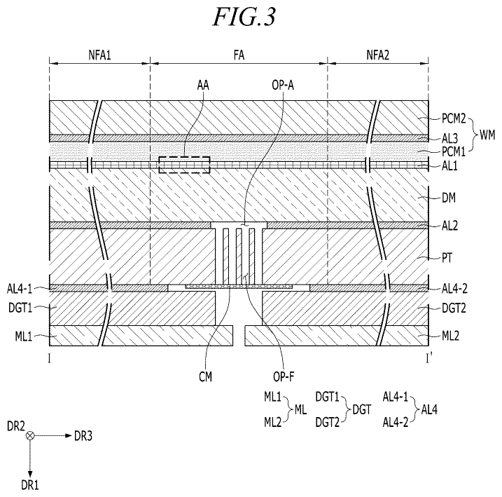

FIG. 2 is an exploded perspective view illustrating, as an example, the electronic device ED according to an embodiment of the inventive concept. FIG. 3 is a view illustrating, as an example, a portion of a cross-section taken along line I-I′ of FIG. 1A.

Referring to FIGS. 2 and 3, the electronic device ED according to an embodiment of the inventive concept may include a window module WM, a display module DM, a support plate PT, a cover member CM, digitizers DGT1 and DGT2, and metal layers ML1 and ML2.

The window module WM and the display module DM may be attached to each other by a first adhesive layer AL1. The display module DM and the support plate PT may be attached to each other by a second adhesive layer AL2. An adhesive opening OP-A may be defined in the second adhesive layer AL2. Each of the first adhesive layer AL1 and the second adhesive layer AL2 may include a pressure sensitive adhesive (PSA). However, the embodiment of the inventive concept is not limited thereto. For example, each of the first adhesive layer AL1 and the second adhesive layer AL2 may include an optically clear adhesive (OCA) or an optically clear resin (OCR).

The window module WM may be disposed on the display module DM to define an appearance of the electronic device ED and protect the display module DM. The window module WM may include a flexible material. Thus, when the electronic device ED is folded based on the folding axis FX (refer to FIG. 1A), the window module WM may be bent together with the electronic device ED.

The window module WM may include a first protection member PCM1, a third adhesive layer AL3, and a second protection member PCM2.

The first protection member PCM1 may include a transparent material. Thus, light emitted from the display module DM may pass through the first protection member PCM1. For example, the first protection member PCM1 may include at least one of a glass substrate or a synthetic resin film. The synthetic resin film may include at least one of polyimide (PI) or polyethylene terephthalate (PET). Also, the first protection member PCM1 may include an elastomer.

In an embodiment of the inventive concept, the first protection member PCM1 may have a thickness that is greater than or equal to 15 μm and less than or equal to 100 μm. Preferably, the first protection member PCM1 may have a thickness that is greater than or equal to 16 μm and less than or equal to 85 μm. When the thickness of the first protection member PCM1 is less than 16 μm, the first protection member PCM1 may not effectively protect components disposed there below. When the thickness of the first protection member PCM1 is greater than 85 μm, folding or bending characteristics of the electronic device ED may be compromised by the increased thickness of the first protection member PCM1.

In an embodiment of the inventive concept, the first protection member PCM1 may be formed by bonding a plurality of synthetic resin films using an adhesive. In another embodiment of the inventive concept, the first protection member PCM1 may be formed by bonding a glass substrate to at least one synthetic resin film using an adhesive.

The third adhesive layer AL3 may be disposed between the second protection member PCM2 and the first protection member PCM1 to bond the second protection member PCM2 and the first protection member PCM1 to each other.

The second protection member PCM2 may be disposed on the first protection member PCM1 to protect the first protection member PCM1 and functional layers disposed below the first protection member PCM1 against external pressure, thereby preventing the display module DM from being deformed.

The second protection member PCM2 may include a flexible plastic material. The second protection member PCM2 may include at least one of polyimide (PI) or polyethylene terephthalate (PET).

A first non-folding area NFA1, a folding area FA, and a second non-folding area NFA2 may be defined on the electronic device ED. The folding area FA may overlap the folding axis FX in FIGS. 1A and 1B. The folding area FA of the electronic device ED may include a flexible material. Thus, when the electronic device ED is folded about the folding axis FX, the folding area FA may be also bent. The folding area FA may be disposed between the first non-folding area NFA1 and the second non-folding area NFA2.

The support plate PT may be disposed below the display module DM to support the display module DM. The support plate PT may be disposed between the display module DM and the cover member CM.

The support plate PT may include an insulating material or a non-metallic material. For example, the support plate PT may include carbon fiber reinforced plastic (CFRP) or glass fiber reinforced plastic (GFRP).

A plurality of folding openings OP-F may be defined in the support plate PT. The plurality of folding openings OP-F may overlap and be connected to the adhesive opening OP-A. The plurality of folding openings OP-F may be arranged to have a lattice shape on a plane. The folding area FA may have improved flexibility by the plurality of folding openings OP-F. Also, the plurality of folding openings OP-F may overlap the folding area FA in the first direction DR1.

The cover member CM may be disposed below the support plate PT. The cover member CM may prevent foreign substances from being introduced into the display module DM through the plurality of folding openings OP-F.

The electronic device ED according to an embodiment of the inventive concept may include a fourth adhesive layer AL4-1 and AL4-2.

One portion AL4-1 of the fourth adhesive layer AL4 may be disposed between the support plate PT and the first digitizer DGT1 to attach the support plate PT and the first digitizer DGT1 to each other. The other portion AL4-2 of the fourth adhesive layer AL4 may be disposed between the support plate PT and the second digitizer DGT2 to attach the support plate PT and the second digitizer DGT2 to each other.

The digitizers DGT1 and DGT2 may be disposed below the support plate PT. The digitizers DGT1 and DGT2 may include the first digitizer DGT1 and the second digitizer DGT2. The first digitizer DGT1 may be disposed in a position that overlaps the first non-folding area NFA1. The second digitizer DGT2 may be disposed in a position that overlaps the second non-folding area NFA2. A portion of each of the first digitizer DGT1 and the second digitizer DGT2 may be disposed below the cover member CM. The first digitizer DGT1 may be spaced apart by a predetermined gap from the second digitizer DGT2. The predetermined gap may be in a range from about 0.3 mm to about 3 mm, measured in the third direction DR3. However, the embodiment of the inventive concept is not limited thereto.

The digitizers DGT1 and DGT2 may sense an input generated by an electromagnetic pen (not shown). The digitizers DGT1 and DGT2 may be driven by a method using electro magnetic resonance (EMR) caused by electromagnetic induction.

The digitizers DGT1 and DGT2 may include a plurality of loop coils (not shown). The plurality of loop coils may generate a magnetic field having a preset resonant frequency with the electronic pen. The magnetic field generated by the plurality of loop coils is applied to an LC resonance circuit provided by an inductor and a capacitor of the electronic pen. The coil generates a current by a received magnetic field and transmits the generated current to the capacitor. Accordingly, the capacitor charges the current input from the coil and discharges the charged current to the coil. As a result, the magnetic field having a resonant frequency is emitted to the coil. The magnetic field emitted by the electronic pen may be absorbed again by the plurality of loop coils, and thus the electronic pen may determine an adjacent position of the display panel DP.

Although not separately shown in this specification, an electromagnetic shielding layer (not shown) may be disposed below the digitizers DGT1 and DGT2. The electromagnetic shielding layer (not shown) may perform an electromagnetic shielding function. For example, the electromagnetic shielding layer may block an electromagnetic wave generated by components disposed below the digitizers DGT1 and DGT2, thus improving the sensing sensitivity of the digitizers DGT1 and DGT2.

The electromagnetic shielding layer (not shown) may include magnetic metal powder (MMP), ferrite, or invar. Also, the electromagnetic shielding layer (not shown) may include iron (Fe), silicon (Si), and/or aluminum (Al).

The metal layers ML1 and ML2 may be disposed below the digitizers DGT and DGT2, respectively. The metal layers ML1 and ML2 may include a first metal layer ML1 and a second metal layer ML2. The first metal layer ML1 may overlap the first non-folding area NFA1. The second metal layer ML2 may overlap the second non-folding area NFA2.

The metal layers ML1 and ML2 may include stainless steel (SUS), copper (Cu), or aluminum (Al). However, the embodiment of the inventive concept is not limited thereto.

Although not separately shown in this specification, a heat dissipation layer (not shown) may be disposed below the metal layers ML1 and ML2. The heat dissipation layer may release heat generated during operations of the digitizers DGT1 and DGT2 to the outside.

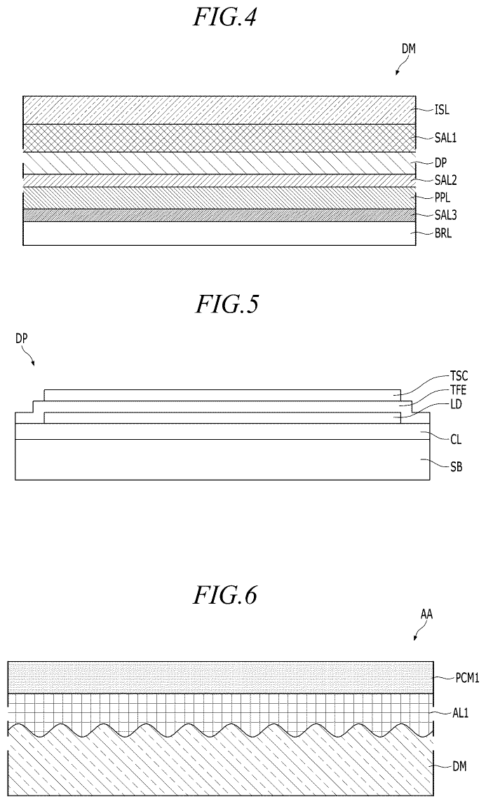

FIG. 4 is a view illustrating, as an example, a portion of a cross-section of the display module DM according to an embodiment of the inventive concept.

The display module DM may include a shock absorbing layer ISL, a first sub-adhesive layer SAL1, a display panel DP, a second sub-adhesive layer SAL2, a panel protection layer PPL, a third sub-adhesive layer SAL3, and a barrier layer BRL.

The shock absorbing layer ISL may be disposed on the display panel DP. The shock absorbing layer ISL may absorb a shock transmitted from above the display panel DP to protect the display panel DP. The shock absorbing layer ISL may include a flexible plastic material. For example, the shock absorbing layer ISL may include a synthetic resin film. The synthetic resin film may include at least one of polyimide (PI), polycarbonate, polyamide, triacetylcellulose, or polyethylene terephthalate (PET).

The first sub-adhesive layer SAL1 may be disposed between the shock absorbing layer ISL and the display panel DP to bond the shock absorbing layer ISL and the display panel DP to each other.

The display panel DP may emit light. The display panel DP may include a plurality of pixels, and each of the pixels may include a light emitting element and a pixel circuit that controls a value of a current flowing through the light emitting element. For example, the display panel DP may be one of an organic light emitting display panel, a quantum dot light emitting display panel, a micro-LED display panel, a liquid crystal display panel, an electrophoretic display panel, and an electrowetting display panel. The organic light emitting display panel may include a light emitting layer containing an organic light emitting material. The inorganic light emitting display panel may include a quantum dot light emitting display panel and a micro-light emitting display panel based on an inorganic material.

The second sub-adhesive layer SAL2 may be disposed between the display panel DP and the panel protection layer PPL to bond the display panel DP and the panel protection layer PPL to each other.

The panel protection layer PPL may be disposed below the display panel DP. The panel protection layer PPL may absorb a shock transmitted from below the display panel DP to protect the display panel DP. The panel protection layer PPL may include a flexible plastic material. For example, the panel protection layer PPL may include polyethylene terephthalate (PET).

The third sub-adhesive layer SAL3 may be disposed between the panel protection layer PPL and the barrier layer BRL to bonding the panel protection layer PPL and the barrier layer BRL to each other.

The barrier layer BRL may be disposed below the panel protection layer PPL. The barrier layer BRL may prevent the display panel DP from being pressed and deformed. For example, the barrier layer BRL may include at least one of polyimide (PI) or polyethylene terephthalate (PET).

FIG. 5 is a view illustrating, as an example, a cross-section of the display panel DP according to an embodiment of the inventive concept.

Referring to FIG. 5, the display panel DP may include a base layer SB, a circuit layer CL, a light emitting element layer LD, an encapsulation layer TFE, and a touch sensing circuit TSC.

The base layer SB may provide a base on which the circuit layer CL is disposed. The base layer SB may have a flexible property that allows bending, folding, or rolling. In an embodiment of the inventive concept, the base layer SB may include a glass substrate, a metal substrate, or a polymer substrate.

The base layer SB may include polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polycarbonate (PC), cellulosetriacetate (CAT), cellulose acetate propionate (CAP), or a combination thereof. However, the embodiment of the inventive concept is not limited thereto.

The circuit layer CL may be disposed on the base layer SB. The circuit layer CL may include a conductive pattern (not shown), a semiconductor pattern (not shown), a plurality of insulation layers (not shown), and a signal line (not shown).

The light emitting element layer LD may be disposed on the circuit layer CL. The light emitting element layer LD may include electrodes (not shown), functional layers (not shown), and a light emitting element (not shown). The light emitting element may include an organic light emitting material, an inorganic light emitting material, an organic-inorganic light emitting material, a quantum dot, a quantum rod, a micro-LED, or a nano-LED.

The encapsulation layer TFE may be disposed on the light emitting element layer LD. The encapsulation layer TFE may protect the light emitting element layer LD from foreign substances such as moisture, oxygen, and dust particles. The encapsulation layer TFE may include an inorganic layer and an organic layer. For example, the encapsulation layer TFE may have a structure in which a first inorganic layer (not shown), an organic layer (not shown), and a second inorganic layer (not shown) are sequentially laminated.

The touch sensing circuit TSC may be disposed on the display panel DP. The touch sensing circuit TSC may be driven by a capacitive method or a resistive film method. The touch sensing circuit TSC may detect a position or intensity of the touch. The touch sensing circuit TSC may include sensing electrodes that are insulated from each other, routing lines that are connected to corresponding sensing electrodes, and at least one sensing insulation layer.

An anti-reflection layer (not shown) may be disposed on the touch sensing circuit TSC. The anti-reflection layer (not shown) may reduce a reflectance of external light incident from the outside. The anti-reflection layer (not shown) may include color filters.

FIG. 6 is an enlarged view illustrating a portion AA of FIG. 3.

Referring to FIG. 6, a top surface of the display module DM may be uneven and have a high surface roughness.

Accordingly, a bottom surface of the first adhesive layer AL1 disposed on the display module DM may also be uneven and have a high surface roughness, in correspondence to the top surface of the display module DM. However, since the first adhesive layer AL1 has a flat top surface, the top surface of the first adhesive layer AL1 may have a surface roughness less than that of the bottom surface of the first adhesive layer AL1.

In an embodiment of the inventive concept, the first adhesive layer AL1 may include a first initiator and a second initiator that is different from the first initiator.

In an embodiment of the inventive concept, the first initiator may be a material that initiates a polymerization reaction when heat having a predetermined temperature is applied. For example, the first initiator may include azobisisobutyronitrile. However, the embodiment of the inventive concept is not limited thereto.

In an embodiment of the inventive concept, the second initiator may be a material that initiates a polymerization reaction when light having a predetermined wavelength is applied. For example, the second initiator may include at least one of a ketone-based material such as benzophenone and 2-Chloro-thioxanthone and a benzil ketone-based material such as 2,2-dimethoxy-2phenyl-acetophenone or hydroxy-cyclohexyl-phenyl.

In an embodiment of the inventive concept, the second adhesive layer AL2 (refer to FIG. 3) may include a third initiator. The third initiator may be different from the first initiator and the second initiator. The second adhesive layer AL2 (refer to FIG. 3) may further include the first initiator.

In an embodiment of the inventive concept, the third initiator may be a material that initiates a polymerization reaction when a predetermined amount of heat is applied. A temperature at which the third initiator initiates the polymerization reaction may be different from that at which the first initiator initiates the polymerization reaction.

Thus, the first adhesive layer AL1 may include a thermosetting initiator that initiates a polymerization reaction in response to a first predetermined temperature and a photopolymerization initiator that initiates a polymerization reaction in response to light. As for the second adhesive layer AL2, it may include two kinds of thermosetting initiators that initiate the polymerization reaction in response to two different predetermined temperatures, and not include a photopolymerization initiator. Since the first protection member PCM1 disposed on the first adhesive layer AL1 may include a transparent material and thus allow light to pass therethrough, the first adhesive layer AL1 may receive light during a manufacturing process. Thus, the photopolymerization initiator of the first adhesive layer AL1 may initiate a polymerization reaction. On the other hand, the display module DM and the support plate PT, which are disposed on both sides of the second adhesive layer AL2, respectively, may not transmit light therethrough. Accordingly, since the second adhesive layer AL2 may not initiate the polymerization reaction using light, the second adhesive layer AL2 includes the thermosetting initiators but not a photopolymerization initiator.

As described above, since the kinds of the initiators of the first adhesive layer AL1 are different from those of the initiators of the second adhesive layer AL2, the first adhesive layer AL1 and the second adhesive layer AL2 have different surface roughnesses from each other. As used herein, an initiator starting a reaction “in response to a predetermined temperature” is intended to mean that the predetermined temperature or a higher temperature would start the reaction. However, in practical manufacturing processes, it may be preferable to limit the applied temperature to prevent damage.

In an embodiment of the inventive concept, the first adhesive layer AL1 and the second adhesive layer AL2 may not be heated to temperatures exceeding a critical temperature. The critical temperature may be higher than the temperature at which the polymerization reaction starts. If the first adhesive layer AL1 or the second adhesive layer AL2 is heated above the critical temperature, surrounding components may be damaged, such as the display module DM.

Specifically, the first adhesive layer AL1 has the flat top surface and the uneven bottom surface while the second adhesive layer AL2 may have an uneven top surface and an uneven bottom surface. Thus, the top surface of the second adhesive layer AL2 may have a surface roughness greater than that of the top surface of the first adhesive layer AL1.

Although the first initiator is referred to as the thermosetting initiator and the second initiator is referred to as the photopolymerization initiator in an example, the embodiment of the inventive concept is not limited thereto. In another embodiment of the inventive concept, the first initiator may be a thermosetting initiator or a photopolymerization initiator, and the second initiator may be a photopolymerization initiator or a moisture curing initiator.

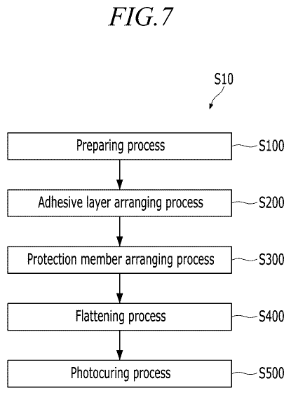

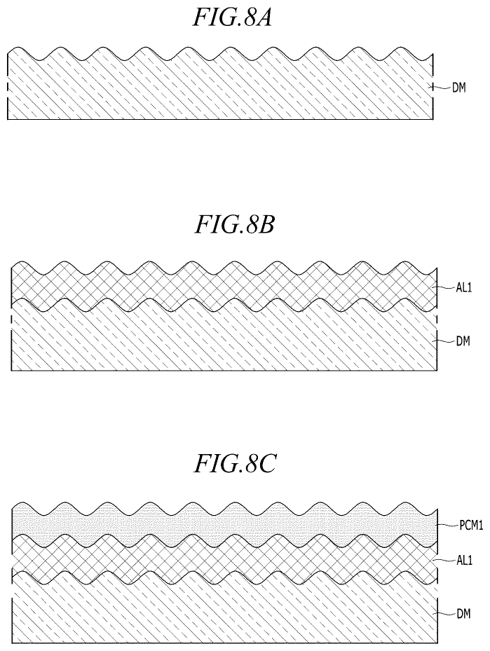

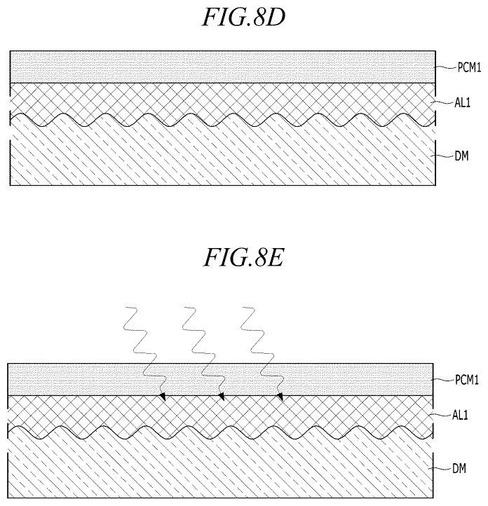

FIG. 7 is a flowchart representing a method S10 for manufacturing a display device according to an embodiment of the inventive concept. FIGS. 8A to 8E are views corresponding to respective processes of the method S10 for manufacturing the display device.

The method S10 for manufacturing the display device may include a preparing process S100, an adhesive layer arranging process S200, a protection member arranging process S300, a flattening process S400, and a photocuring process S500.

Referring to FIGS. 7 and 8A, a display module DM may be prepared in the preparing process S100. Since the display module DM has a structure in which a plurality of thin layers are laminated to be folded, a top surface of the display module DM has an uneven shape due to the thin layers.

Referring to FIGS. 7 and 8B, the first adhesive layer AL1 may be arranged on the display module DM in the adhesive layer arranging process S200.

Each of top and bottom surfaces of the first adhesive layer AL1 may also have an uneven shape in accordance with the uneven shape of the display module DM directly after the first adhesive layer AL1 is arranged on the display module DM. Also, before the process of arranging the first adhesive layer AL1 on the display module DM, both side surfaces of the first adhesive layer AL1 may be protected by release films. Since the release films contain silica particles, the top and bottom surfaces of the first adhesive layer AL1 may also have an uneven shape by the silica particles. That is, each of the top and bottom surfaces of the first adhesive layer AL1 may have a great surface roughness due to the shape of the display module DM and the silica particles.

In the adhesive layer arranging process S200, a creep value of the first adhesive layer AL1 may be greater than or equal to 150% and less than or equal to 300% when a stress of 2000 Pa is applied for 10 minutes at a temperature of 25° C. When the creep value of the first adhesive layer AL1 is less than 150% when a stress of 2000 Pa is applied for 10 minutes at a temperature of 25° C., the first adhesive layer AL1 is not sufficiently flattened because a degree of deformation of the first adhesive layer AL1 is extremely small in the flattening process S400 that will be described below. When the creep value of the first adhesive layer AL1 is greater than 300% when a stress of 2000 Pa is applied for 10 minutes at a temperature of 25° C., the degree of deformation of the first adhesive layer AL1 excessively increases when the first protection member PCM1 is arranged in the protection member arranging process S300 that will be described below. Accordingly, each of the upper and lower surfaces of the first adhesive layer AL1 becomes even more uneven instead of being flattened. Also, since the creep value of the first adhesive layer AL1 is extremely great, process convenience decreases when the first adhesive layer AL1 is arranged.

Referring to FIG. 7 and FIG. 8C, the first protection member PCM1 including a transparent material may be arranged on the first adhesive layer AL1 in the protection member arranging process S300. The first protection member PCM1 has a small thickness and a flexible property. Thus, each of top and bottom surfaces of the first protection member PCM1 may also have an uneven shape in accordance with the uneven shape of the first adhesive layer AL1.

Referring to FIGS. 7 and 8D, a predetermined time may elapse in the flattening process S400. The predetermined time may be greater than or equal to 50 minutes and less than or equal to 24 hours. As described in the adhesive layer arranging process S200, the top surface of the first adhesive layer AL1 may become flattened as time elapses due to creep characteristics of the first adhesive layer AL1. As the top surface of the first adhesive layer AL1 becomes flattened, each of top and bottom surfaces of the first protection member PCM1 may also become flattened.

Referring to FIGS. 7 and 8E, the first adhesive layer AL1 may be cured as light (e.g., UV light) having a predetermined wavelength is radiated onto the first protection member PCM1 in the photocuring process S500. When the creep value of the first adhesive layer AL1 is greater than or equal to 80% and less than or equal to 130% when a stress of 2000 Pa is applied for 10 minutes at a temperature of 25° C. Since the creep value of the first adhesive layer AL1 decreases by the photocuring process S500, the top surface of the first adhesive layer AL1 may maintain a flattened state. As the top surface of the first adhesive layer AL1 becomes flattened, the surface roughness of each of components arranged on the first adhesive layer AL1 may decrease. Accordingly, since a display area DA of an electronic device ED according to an embodiment of the inventive concept has a low surface roughness, the display area DA having a high quality may be provided.

Although FIGS. 8A to 8E are described based on the first adhesive layer AL1, the processes described in FIGS. 8A to 8E may be applied to second to fourth adhesive layers AL2 to AL4 and sub-adhesive layers SAL1, SAL2, and SAL3 in another embodiment of the inventive concept.

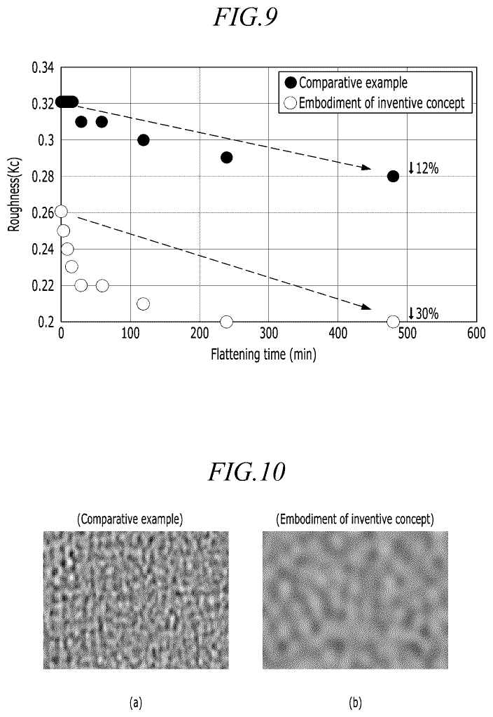

FIG. 9 is a graph representing a change in roughness of the display area DA of the electronic device ED according to an elapsed time in the flattening process S400. In FIG. 9, a Kc value representing a degree of roughness is measured by phase measuring deflectometry (PMD), which is a curvature value obtained by measuring a waviness having a wavelength that is greater than or equal to 1.0 mm and less than or equal to 3.0 mm.

TABLE 1

| | Comparative | Embodiment of |
|---|---|---|
| Classification | example | inventive concept |
| Creep value of | 54.5% | 156% |
| adhesive layer | | |

| | | | | | |
|---|---|---|---|---|---|
| Flattening time | Time | 0 hr | 24 hr | 0 hr | 24 hr |
| Roughness | Kc | 0.32 | 0.26 | 0.26 | 0.12 |

In [Table 1], data of a comparative example is compared with data of an embodiment of the inventive concept in relation to the graph of FIG. 9. Referring to FIG. 9 and [Table 1], a creep value of the adhesive layer of the comparative example in the adhesive layer arranging process S200 is 54.5% when a stress of 2000 Pa is applied for 10 minutes at a temperature of 25° C. The creep value of the first adhesive layer AL1 in the adhesive layer arranging process S200 according to an embodiment of the inventive concept is 156% when a stress of 2000 Pa is applied for 10 minutes at a temperature of 25° C.

The comparative example relates to a change in roughness when an adhesive layer having a creep value less than that of the first adhesive layer AL1 according to an embodiment of the inventive concept is used. Since the adhesive layer of the comparative example has a low creep value, the Kc value decreases by only about 12% when about 500 minutes elapses.

On the other hand, since the first adhesive layer AL1 according to an embodiment of the inventive concept has a creep value greater than that of the adhesive layer of the comparative example, the Kc value decreases by about 30% when about 500 minutes elapses.

According to an embodiment of the inventive concept, it may be confirmed that the Kc value decreases to about 0.22 when 50 minutes elapses, and the Kc value further decreases to about 0.20 when 500 minutes elapses. Also, the Kc value further decreases to about 0.12 when 24 hours elapses.

When a waiting time is less than 50 minutes in the flattening process S400, the Kc value does not decrease sufficiently, and thus, the decreased Kc value is not enough to improve a display quality. Also, when a waiting time is greater than 24 hours in the flattening process S400, the waiting time increases excessively, and thus, an efficiency of a manufacturing process may decrease. Thus, it may be confirmed through FIG. 9 that the waiting time for flattening in the flattening process S400 is greater than or equal to 50 minutes and less than or equal to 24 hours.

As described above, as the Kc value of the first adhesive layer AL1 decreases, the Kc value of each of other components disposed on the first adhesive layer AL1 may also decrease. Specifically, at least one of the first adhesive layer AL1, the first protection member PCM1, the third adhesive layer AL3, and the second protection member PCM2 may have a Kc value greater than or equal to 0.1 and less than or equal to 0.2.

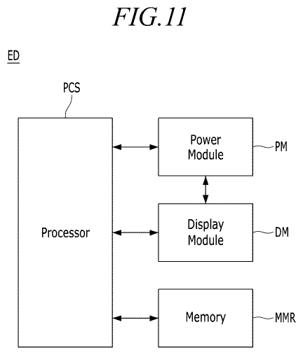

FIG. 10 is a view illustrating a portion of the display area DA of the electronic device ED according to an embodiment of the inventive concept and a portion of a display area of the comparative example. Referring to FIG. 10, it may be confirmed that an embodiment of the inventive concept has a roughness less than that of the comparative example and thus has a better display quality.

FIG. 11 is a block diagram representing, as an example, the electronic device ED according to an embodiment of the inventive concept.

Referring to FIG. 11, the electronic device ED may include a display module DM, a processor PCS, a memory MMR, and a power module PM.

The processor PCS may include at least one of a central processing unit (CPU), an application processor (AP), a graphic processing unit (GPU), a communication processor (CP), an image signal processor (ISP), and a controller.

The memory MMR may store data information required for an operation of the processor PCS or the display module DM. When the processor PCS executes an application stored in the memory MMR, an image data signal and/or an input control signal may be transmitted to the display module DM. The display module DM may process the received signal and output image information through a display screen.

The power module PM may include a power supply module such as a power adapter or a battery device and a power conversion module that converts power supplied by the power supply module to generate power required for an operation of the electronic device ED.

At least one of the above-described components of the electronic device ED may be contained in the display device according to the above-described embodiments. Also, some of the individual modules functionally included in a single module may be contained in the display device, and some thereof may be provided separately from the display device. For example, the display device may include the display module DM, and the processor PCS, the memory MMR, and the power module PM may be provided in the form of a different device in the electronic device ED instead of the display device.

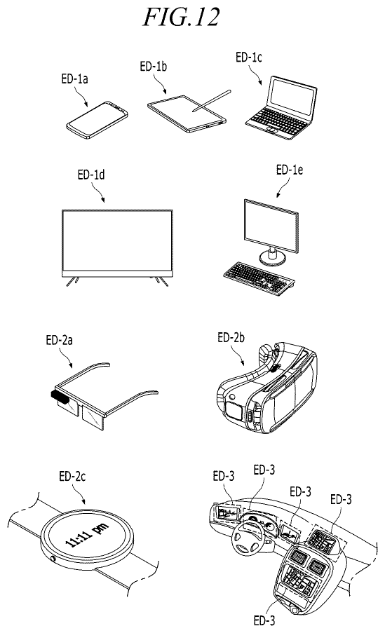

FIG. 12 is a schematic view illustrating, as an example, electronic devices ED according to various embodiments.

Referring to FIG. 12, various electronic devices to which display devices according to embodiments are applied may include an image display electronic device, such as a smartphone ED_1a, a tablet PC ED_1b, a laptop computer ED_1c, a TV ED_1d, and a desktop monitor ED_1e, a wearable electronic device including a display module, such as smart glasses ED_2a, a head-mounted display ED_2b, and a smartwatch ED_2c, and a vehicle electronic device ED_3, such as an vehicle dashboard, a center fascia, a center information display (CID) disposed on a dashboard, and a room mirror display.

The embodiment of the inventive concept may provide the display device having the display area with the low surface roughness, thereby improving the display quality and the electronic device including the same.

The embodiment of the inventive concept may also provide the method for manufacturing a display device having a display area with the low surface roughness.

It will be apparent to those skilled in the art that various modifications and variations may be made in the inventive concept. Thus, it is intended that the present disclosure covers the modifications and variations of this invention provided they come within the scope of the appended claims and their equivalents. Thus, to the maximum extent allowed by law, the scope of the present invention is to be determined by the broadest permissible interpretation of the following claims and their equivalents, and shall not be restricted or limited by the foregoing detailed description.

What is claimed is:

1. A display device comprising:
a display module;
a first adhesive layer disposed on the display module and comprising a first initiator and a second initiator that is different from the first initiator;
a first protection member disposed on the first adhesive layer;
a second adhesive layer disposed below the display module and comprising a third initiator that is different from the first initiator and the second initiator; and
a support plate disposed below the second adhesive layer.

2. The display device of claim 1, wherein the first initiator is a material that initiates a polymerization reaction in response to a first temperature, and
the second initiator is a material that initiates a polymerization reaction in response to light having a predetermined wavelength.

3. The display device of claim 2, wherein the third initiator is a material that initiates a polymerization reaction in response to heat having a second temperature different from the first temperature.

4. The display device of claim 3, wherein the first initiator comprises azobisisobutyronitrile, and
the second initiator comprises at least one of a ketone-based material and a benzil ketone-based material.

5. The display device of claim 1, wherein a bottom surface of the first adhesive layer has a surface roughness greater than that of a top surface of the first adhesive layer.

6. The display device of claim 5, wherein a top surface of the second adhesive layer has a surface roughness greater than that of the top surface of the first adhesive layer.

7. The display device of claim 1, further comprising:
a third adhesive layer disposed on the first protection member; and
a second protection member disposed on the third adhesive layer,
wherein each of the display module, the first adhesive layer, the first protection member, the second adhesive layer, the support plate, the third adhesive layer, and the second protection member is foldable.

8. The display device of claim 7, wherein a plurality of folding openings are defined in the support plate, and
an adhesive opening that overlaps the plurality of folding openings are defined in the second adhesive layer.

9. The display device of claim 7, wherein at least one of the second protection member, the third adhesive layer, the first protection member, and the first adhesive layer has a Kc value greater than or equal to 0.1 and less than or equal to 0.2, and
the Kc value is a value measured by phase measuring deflectometry (PMD), which is a curvature value obtained by measuring a waviness having a wavelength that is greater than or equal to 1.0 mm and less than or equal to 3.0 mm.

10. An electronic device comprising:
a display module;
a first adhesive layer which is disposed on the display module and in which a bottom surface has a surface roughness greater than that of a top surface that is opposite to the bottom surface;
a first protection member disposed on the first adhesive layer;
a second adhesive layer disposed below the display module; and
a support plate disposed below the second adhesive layer.

11. The electronic device of claim 10, wherein the first adhesive layer comprises a first initiator and a second initiator that is different from the first initiator.

12. The electronic device of claim 11, wherein the first initiator is a material that initiates a polymerization reaction in response to a predetermined temperature, and
the second initiator is a material that initiates a polymerization reaction in response to light having a predetermined wavelength.

13. The electronic device of claim 12, wherein the first initiator comprises azobisisobutyronitrile, and
the second initiator comprises at least one of a ketone-based material and a benzil ketone-based material.

14. The electronic device of claim 13, further comprising:
a third adhesive layer disposed on the first protection member; and
a second protection member disposed on the third adhesive layer,
wherein each of the display module, the first adhesive layer, the first protection member, the second adhesive layer, the support plate, the third adhesive layer, and the second protection member is foldable.

15. The electronic device of claim 14, wherein at least one of the second protection member, the third adhesive layer, the first protection member, and the first adhesive layer has a Kc value greater than or equal to 0.1 and less than or equal to 0.2, and
the Kc value is a value measured by phase measuring deflectometry (PMD), which is a curvature value obtained by measuring a waviness having a wavelength that is greater than or equal to 1.0 mm and less than or equal to 3.0 mm.

16. A method of manufacturing a display device, the method comprising:
providing a display module;
arranging an adhesive layer on the display module, wherein a creep value of the adhesive layer is greater than or equal to 150% and less than or equal to 300% when a stress of 2000 Pa is applied for 10 minutes at a temperature of 25° C.;
arranging a protection member containing a transparent material on the adhesive layer; and
flattening the adhesive layer by waiting a predetermined time after the arranging of the protection member.

17. The method of claim 16, further comprising curing the adhesive layer by irradiating the protection member with light having a predetermined wavelength.

18. The method of claim 17, wherein a creep value of the adhesive layer after the photocuring process is greater than or equal to 80% and less than or equal to 130% when a stress of 2000 Pa is applied for 10 minutes at a temperature of 25° C.

19. The method of claim 18, wherein a bottom surface of the adhesive layer has a surface roughness greater than that of a top surface of the adhesive layer.

20. The method of claim 16, wherein the predetermined time is greater than or equal to 50 minutes and less than or equal to 24 hours.
